(19) United States
(12) Patent Application Publication
(10) Pub. No.: US 2005/0272191 A1
(43) Pub. Date: Dec. 8, 2005

(54) Replacement gate process for making a semiconductor device that includes a metal gate electrode

(76) Inventors: Uday Shah, Portland, OR (US); Mark L. Doczy, Beaverton, OR (US); Justin K. Brask, Portland, OR (US); Jack Kavalieros, Portland, OR (US); Matthew V. Metz, Hillsboro, OR (US); Robert S. Chau, Beaverton, OR (US); Chris E. Barns, Portland, OR (US)

Correspondence Address: INTEL CORPORATION, P.O. BOX 5326, SANTA CLARA, CA, 95056-5326, US

(21) Appl. No.: 10/861,727

(22) Filed: Jun. 3, 2004

(51) Int. Cl. H01L 21/338; H01L 21/8234; H01L 21/3205

(52) U.S. Cl. 438/197; 438/199; 438/585; 438/275; 438/595

(57) ABSTRACT

A method for making a semiconductor device is described. That method comprises forming a sacrificial layer on a substrate, and forming a trench within the sacrificial layer. After forming a dummy gate electrode within the trench, a hard mask is formed on the dummy gate electrode and within the trench.

### FIELD OF THE INVENTION

The present invention relates to methods for making semiconductor devices, in particular, semiconductor devices with metal gate electrodes.

### BACKGROUND OF THE INVENTION

When making a CMOS device that includes metal gate electrodes, a replacement gate process may be used to form gate electrodes from different metals. In that process, a first polysilicon layer, bracketed by a pair of spacers, is removed to create a trench between the spacers. The trench is filled with a first metal. A second polysilicon layer is then removed, and replaced with a second metal that differs from the first metal.

In such a process, it may be necessary to form a hard mask on the polysilicon layers to minimize silicide formation, when the transistors' source and drain regions are covered with a silicide. Although such a hard mask may protect the upper surface of the polysilicon layers, the upper corners of those layers may be exposed, when the spacers are formed. Silicide may form at those exposed corners, when the source and drain regions are silicided, which may adversely impact the subsequent polysilicon removal steps.

Accordingly, there is a need for an improved method for making a semiconductor device that includes metal gate electrodes. There is a need for a replacement gate process that replaces polysilicon layers with metal layers, which is not adversely affected by silicide formation on the polysilicon layers. The present invention provides such a method.

### BRIEF DESCRIPTION OF THE DRAWINGS

FIGS. 1a-1g represent cross-sections of structures that may be formed when carrying out an embodiment of the method of the present invention.

FIGS. 2a-2j represent cross-sections of structures that may be formed when the method of the present invention is applied to a replacement gate process.

Features shown in these figures are not intended to be drawn to scale.

### DETAILED DESCRIPTION OF THE PRESENT INVENTION

A method for making a semiconductor device is described. That method comprises forming a sacrificial layer on a substrate, and forming a trench within the sacrificial layer. After forming a dummy gate electrode within the trench, a hard mask is formed on the dummy gate electrode and within the trench. In the following description, a number of details are set forth to provide a thorough understanding of the present invention. It will be apparent to those skilled in the art, however, that the invention may be practiced in many ways other than those expressly described here. The invention is thus not limited by the specific details disclosed below.

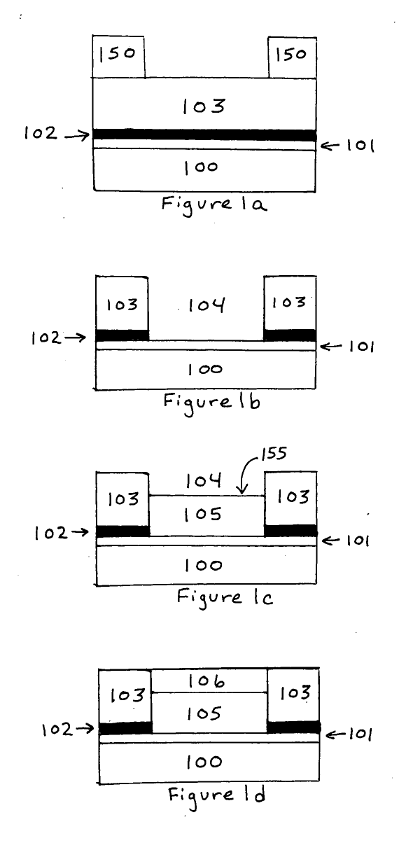

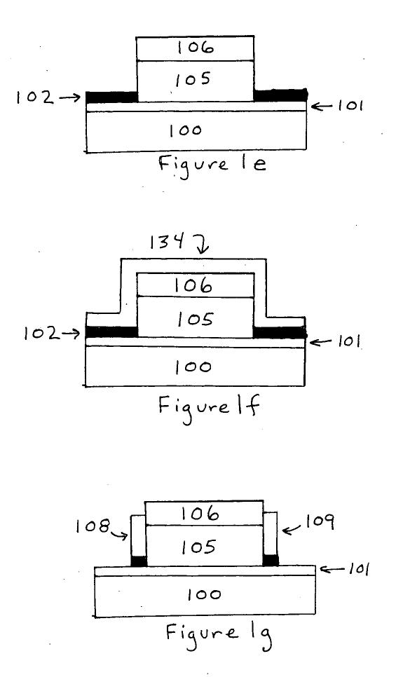

FIGS. 1a-1g illustrate structures that may be formed, when carrying out an embodiment of the method of the present invention. Initially, dielectric layer 101 is formed on substrate 100, etch stop layer 102 is formed on dielectric layer 101, and sacrificial layer 103 is formed on etch stop layer 102. Masking layer 150 is then deposited and patterned on sacrificial layer 103 to generate the FIG. 1a structure. Masking layer 150 covers part of sacrificial layer 103, but also leaves part of that layer exposed.

Substrate 100 may comprise a bulk silicon or silicon-on-insulator substructure. Alternatively, substrate 100 may comprise other materials—which may or may not be combined with silicon—such as: germanium, indium antimonide, lead telluride, indium arsenide, indium phosphide, gallium arsenide, or gallium antimonide. Although a few examples of materials from which substrate 100 may be formed are described here, any material that may serve as a foundation upon which a semiconductor device may be built falls within the spirit and scope of the present invention.

Dielectric layer 101 may comprise silicon dioxide, a nitrided silicon dioxide, a high-k dielectric layer, or other materials that may protect substrate 100. Etch stop layer 102 preferably comprises silicon nitride. Sacrificial layer 103 may comprise a dielectric material or other type of material that may provide a support structure for a subsequently created dummy gate electrode and hard mask. Sacrificial layer 103 must be thick enough to accommodate those subsequently formed structures. In a preferred embodiment, sacrificial layer 103 comprises silicon dioxide, which may or may not be doped with fluorine, carbon, or other elements. Dielectric layer 101, etch stop layer 102, and sacrificial layer 103 may be formed using conventional process steps. Masking layer 150 may comprise any typical masking material and may be deposited and patterned using conventional techniques.

After forming the figure la structure, the exposed part of sacrificial layer 103 is removed. When sacrificial layer 103 comprises silicon dioxide, that layer may be etched using a generally applied process for etching silicon dioxide. Etch stop layer 102 should be thick enough to prevent that process from reaching dielectric layer 101. After the exposed part of sacrificial layer 103 is removed, the underlying part of etch stop layer 102 is removed, generating trench 104. If etch stop layer 102 comprises silicon nitride, that layer may be etched using a generally applied process for etching silicon nitride. After removing that part of etch stop layer 102, masking layer 150 is removed, e.g., via conventional process steps, generating the FIG. 1b structure.

Dummy gate electrode 105 is then formed within trench 104, as shown in FIG. 1c. Dummy gate electrode 105 preferably comprises a polysilicon containing layer. When it comprises a polysilicon containing layer, dummy gate electrode 105 may be formed by initially depositing a polysilicon layer onto sacrificial layer 103 and into trench 104, e.g., by using generally applied polysilicon deposition techniques. That layer may then be removed from sacrificial layer 103, e.g., by using a conventional chemical mechanical polishing (“CMP”) operation, such that it remains within trench 104 only. In this embodiment, the upper part of such a polysilicon layer is then removed so that upper surface 155 of dummy gate electrode 105 is recessed below the surface of sacrificial layer 103, as FIG. 1c illustrates. An appropriate wet etch process may be used to remove the upper part of a polysilicon layer, as will be apparent to those skilled in the art. Dummy gate electrode 105 preferably is between about 100 and about 2,000 angstroms thick, and more preferably is between about 500 and about 1,600 angstroms thick.

After forming dummy gate electrode 105, hard mask 106 is formed on dummy gate electrode 105 and within trench 104, as FIG. 1d illustrates. In a preferred embodiment, hard mask 106 comprises silicon nitride and is formed by depositing a silicon nitride layer onto sacrificial layer 103 and into trench 104, e.g., by using a conventional silicon nitride deposition process. That layer may then be removed from sacrificial layer 103, e.g., by using a conventional CMP step, such that it remains within trench 104 only.

By forming hard mask 106 within trench 104, the method of the present invention may offer several advantages, when compared to current processes for forming a hard mask on a polysilicon containing layer. In current processes, lithographic and aspect ratio constraints may dictate a maximum hard mask thickness. A restricted hard mask thickness may render it difficult to maintain cross wafer uniformity. In addition, a relatively thin hard mask may be susceptible to meaningful hard mask damage, when ions are subsequently implanted into source and drain regions. Perhaps more importantly, at least when applied to a replacement gate process, a relatively thin hard mask may not adequately protect an underlying polysilicon layer, when the source and drain regions are silicided. As a result, a significant part of the polysilicon layer may be silicided, which may inhibit the effective removal of that layer prior to forming a metal gate electrode.

The method of the present invention enables a relatively thick hard mask to be formed within trench 104—unaffected by lithographic or aspect ratio concerns. Such a hard mask may enable improved cross wafer uniformity, may better withstand implant damage, and may better protect an underlying polysilicon layer, when source and drain regions are silicided. In addition, the method of the present invention permits the profile of trench 104 to be tailored to suit various processes. For example, when applied to a replacement gate process, it may be advantageous to form a trench that is narrower at the bottom than at the top. When a polysilicon layer fills such a trench, that layer will be wider at its top surface than at its bottom surface. When such a layer is removed to form a second trench, the resulting trench will likewise be wider at the top than at the bottom. It may be easier to fill such a trench with a metal layer, than to fill a trench that is wider at the bottom than at the top or that has substantially vertical sides.

By forming hard mask 106 within trench 104, hard mask 106 may exceed 500 angstroms in thickness without adversely affecting the overall process, although preferably hard mask 106 is between about 200 and about 500 angstroms thick. After forming the FIG. 1d structure, sacrificial layer 103 is removed, as FIG. 1e illustrates. Sacrificial layer 103 may be removed using conventional process steps. In this embodiment, etch stop layer 102 and the underlying part of dielectric layer 101 are retained.

After forming the FIG. 1e structure, spacers are formed on opposite sides of dummy gate electrode 105. When those spacers comprise silicon nitride, they may be formed in the following way. First, a silicon nitride layer of substantially uniform thickness—preferably less than about 1000 angstroms thick—is deposited over the entire structure, producing the structure shown in FIG. 1f. Conventional deposition processes may be used to generate that structure.

Silicon nitride layer 134 may be etched using a conventional process for anisotropically etching silicon nitride to create the FIG. 1g structure. As FIG. 1g illustrates, etch stop layer 102 may be removed at the same time. When hard mask 106 comprises silicon nitride, a timed etch may be used to prevent that anisotropic etch step from removing a significant part of hard mask 106, when silicon nitride layer 134 and etch stop layer 102 are etched. Because the hard mask was relatively thick when initially formed within the trench, a significant part of it remains after that etch step—even when the hard mask comprises silicon nitride. As a result of the silicon nitride etch step, dummy gate electrode 105 is bracketed by a pair of sidewall spacers 108 and 109. In this embodiment, the exposed part of dielectric layer 101 is retained—although in alternative embodiments it may be removed immediately after the silicon nitride etch step.

As is typically done, it may be desirable to perform an ion implantation step to create lightly implanted regions near dummy gate electrode 105 (that will ultimately serve as tip regions for the device's source and drain regions), prior to forming spacers 108 and 109 on dummy gate electrode 105. When a relatively high energy ion implantation process is applied to form such lightly implanted regions, the implanted ions may penetrate through etch stop layer 102 and dielectric layer 101. If a low energy ion implantation process is used to form lightly implanted regions, then it may be necessary to remove etch stop layer 102 and the underlying part of dielectric layer 101 prior to performing that ion implantation process and prior to forming silicon nitride layer 134.

Also as is typically done, the source and drain regions may be formed, after forming spacers 108 and 109, by implanting ions into substrate 100, followed by applying an appropriate anneal step. Part of those source and drain regions may then be converted to a silicide using well known process steps. Relatively thick hard mask 106 may prevent such a process sequence from converting a meaningful part, if any, of dummy gate electrode 105 to a silicide. When dummy gate electrode 105 comprises polysilicon, an ion implantation and anneal sequence used to form n-type source and drain regions within substrate 100 may dope dummy gate electrode 105 n-type at the same time. Similarly, an ion implantation and anneal sequence used to form p-type source and drain regions within substrate 100 may dope dummy gate electrode 105 p-type.

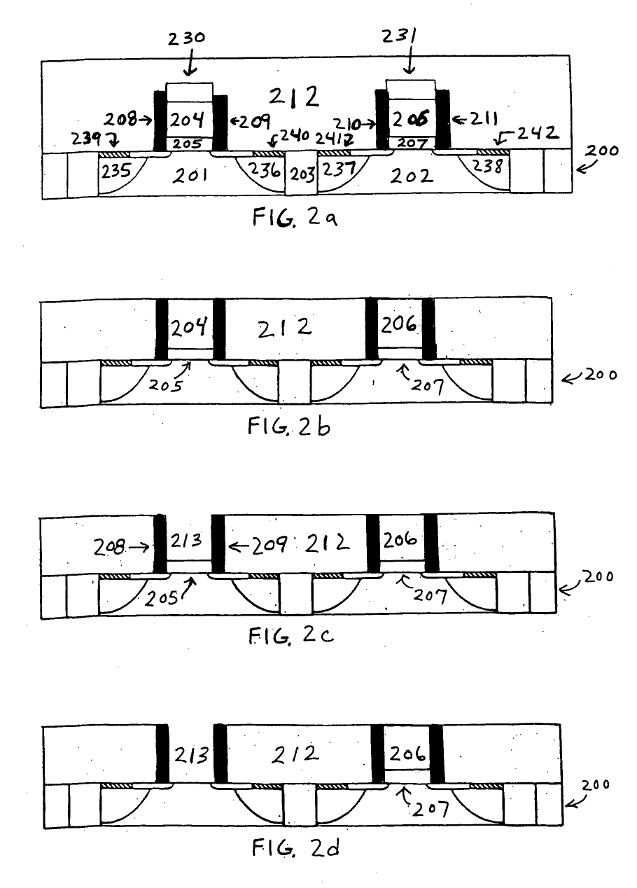

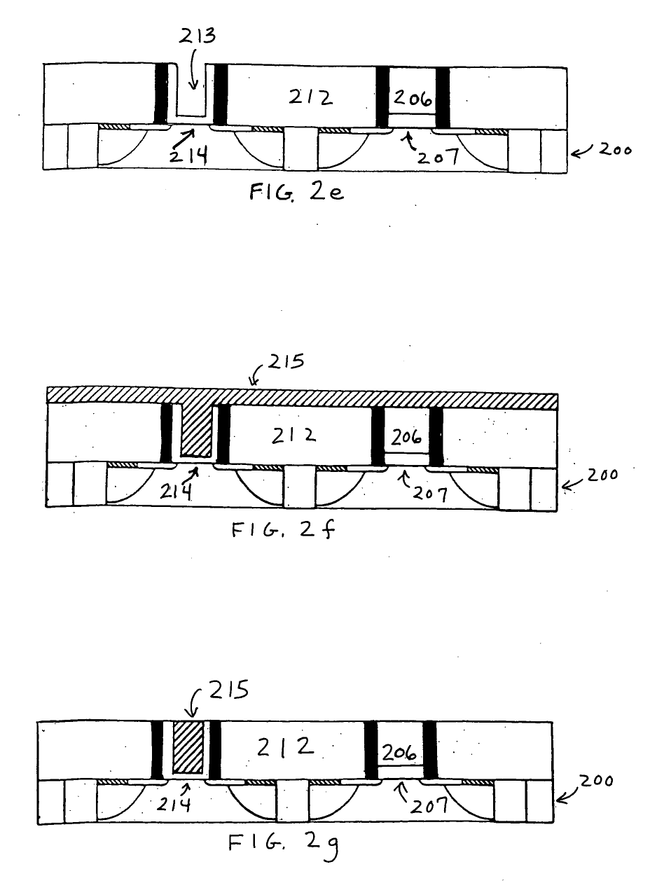

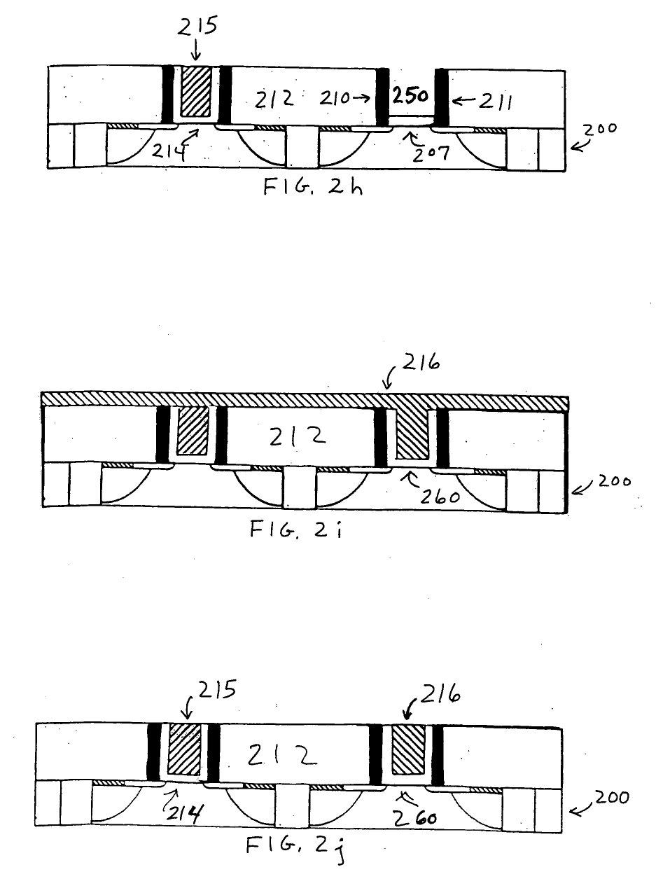

As demonstrated below, the method of the present invention may be applied to form metal gate electrodes using a replacement gate process. FIGS. 2a-2j illustrate structures that may be formed, when integrating the method of the present invention into such a process. FIG. 2a represents an intermediate structure that may be formed when making a CMOS device. That structure includes first part 201 and second part 202 of substrate 200. Isolation region 203 separates first part 201 from second part 202. Isolation region 203 may comprise silicon dioxide, or other materials that may separate the transistor's active regions.

In this embodiment, first polysilicon layer 204 is formed on first dummy dielectric layer 205, and second polysilicon layer 206 is formed on second dummy dielectric layer 207. Hard masks 230 and 231 are formed on polysilicon layers 204 and 206. First dummy dielectric layer 205 and second dummy dielectric layer 207 may each comprise silicon dioxide, or other materials that may protect substrate 200—e.g., silicon oxynitride, silicon nitride, a carbon doped silicon dioxide, or a nitrided silicon dioxide. Polysilicon layers 204 and 206 are preferably between about 100 and about 2,000 angstroms thick, and more preferably between about 500 and about 1,600 angstroms thick. Hard masks 230 and 231 may comprise silicon nitride and preferably are between about 200 and about 500 angstroms thick. The process steps described above may be used to create polysilicon layers 204 and 206 and hard masks 230 and 231.

Polysilicon layer 204 is bracketed by a pair of sidewall spacers 208 and 209, and polysilicon layer 206 is bracketed by a pair of sidewall spacers 210 and 211. Sidewall spacers 208, 209, 210, and 211 may be formed on polysilicon layers 204 and 206 using process steps like those described above. Dielectric layer 212, which may comprise doped or undoped silicon dioxide or a low-k material, covers the underlying structures. By this stage of the process, source and drain regions 235, 236, 237, and 238, which are capped by silicided regions 239, 240, 241, and 242, have already been formed. Conventional process steps, materials, and equipment may be used to generate those structures, as will be apparent to those skilled in the art.

Dielectric layer 212 is removed from hard masks 230 and 231, which are, in turn, removed from polysilicon layers 204 and 206, producing the FIG. 2b structure. A conventional CMP operation may be applied to remove that part of dielectric layer 212, and to remove hard masks 230 and 231. Hard masks 230 and 231 must be removed to expose polysilicon layers 204 and 206. Hard masks 230 and 231 may be polished from the surface of layers 204 and 206, when dielectric layer 212 is polished—as they will have served their purpose by that stage in the process.

After forming the FIG. 2b structure, polysilicon layer 204 is removed to generate trench 213 that is positioned between sidewall spacers 208 and 209—producing the structure shown in FIG. 2c. In a preferred embodiment, a wet etch process that is selective for layer 204 over polysilicon layer 206 is applied to remove layer 204 without removing significant portions of layer 206.

When polysilicon layer 204 is doped n-type, and polysilicon layer 206 is doped p-type (e.g., with boron), such a wet etch process may comprise exposing polysilicon layer 204 to an aqueous solution that comprises a source of hydroxide for a sufficient time at a sufficient temperature to remove substantially all of layer 204. That source of hydroxide may comprise between about 2 and about 30 percent ammonium hydroxide or a tetraalkyl ammonium hydroxide, e.g., tetramethyl ammonium hydroxide (“TMAH”), by volume in deionized water.

Polysilicon layer 204 may be selectively removed by exposing it to a solution, which is maintained at a temperature between about 15° C. and about 90° C. (and preferably below about 40° C.), that comprises between about 2 and about 30 percent ammonium hydroxide by volume in deionized water. During that exposure step, which preferably lasts at least one minute, it may be desirable to apply sonic energy at a frequency of between about 10 KHz and about 2,000 KHz, while dissipating at between about 1 and about 10 watts/cm².

In a particularly preferred embodiment, a polysilicon layer with a thickness of about 1,350 angstroms may be selectively removed by exposing it at about 25° C. for about 30 minutes to a solution that comprises about 15 percent ammonium hydroxide by volume in deionized water, while applying sonic energy at about 1,000 KHz—dissipating at about 5 watts/cm². Such an etch process should remove substantially all of an n-type polysilicon layer without removing a meaningful amount of a p-type polysilicon layer.

As an alternative, polysilicon layer 204 may be selectively removed by exposing it for at least one minute to a solution, which is maintained at a temperature between about 60° C. and about 90° C., that comprises between about 20 and about 30 percent TMAH by volume in deionized water, while applying sonic energy. Removing a polysilicon layer with a thickness of about 1,350 angstroms by exposing it at about 80° C. for about 2 minutes to a solution that comprises about 25 percent TMAH by volume in deionized water (while applying sonic energy at about 1,000 KHz, dissipating at about 5 watts/cm²) may remove substantially all of that layer without removing a significant amount of layer 206.

First dummy dielectric layer 205 should be sufficiently thick to prevent the etchant that is applied to remove polysilicon layer 204 from reaching the channel region that is located beneath first dummy dielectric layer 205. If polysilicon layer 206 is doped with boron, that layer should include that element at a sufficient concentration to ensure that a wet etch process for removing n-type polysilicon layer 204 will not remove a significant amount of p-type polysilicon layer 206.

After removing polysilicon layer 204, first dummy dielectric layer 205 is removed. When first dummy dielectric layer 205 comprises silicon dioxide, it may be removed using an etch process that is selective for silicon dioxide to generate the FIG. 2d structure. Such etch processes include: exposing layer 205 to a solution that includes about 1 percent HF in deionized water, or applying a dry etch process that employs a fluorocarbon based plasma. Layer 205 should be exposed for a limited time, as the etch process for removing layer 205 may also remove part of dielectric layer 212.

After removing first dummy dielectric layer 205, gate dielectric layer 214 is formed on substrate 200 at the bottom of trench 213, generating the FIG. 2e structure. Although gate dielectric layer 214 may comprise any material that may serve as a gate dielectric for an NMOS transistor that includes a metal gate electrode, gate dielectric layer 214 preferably comprises a high-k dielectric material. Some of the materials that may be used to make high-k gate dielectric 214 include: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Particularly preferred are hafnium oxide, zirconium oxide, and aluminum oxide. Although a few examples of materials that may be used to form high-k gate dielectric layer 214 are described here, that layer may be made from other materials.

High-k gate dielectric layer 214 may be formed on substrate 200 using a conventional deposition method, e.g., a conventional chemical vapor deposition (“CVD”), low pressure CVD, or physical vapor deposition (“PVD”) process. Preferably, a conventional atomic layer CVD process is used. In such a process, a metal oxide precursor (e.g., a metal chloride) and steam may be fed at selected flow rates into a CVD reactor, which is then operated at a selected temperature and pressure to generate an atomically smooth interface between substrate 200 and high-k gate dielectric layer 214. The CVD reactor should be operated long enough to form a layer with the desired thickness. In most applications, high-k gate dielectric layer 214 should be less than about 60 angstroms thick, and more preferably between about 5 angstroms and about 40 angstroms thick.

As shown in FIG. 2e, when an atomic layer CVD process is used to form high-k gate dielectric layer 214, that layer will form on the sides of trench 213 in addition to forming on the bottom of that trench. If high-k gate dielectric layer 214 comprises an oxide, it may manifest oxygen vacancies at random surface sites and unacceptable impurity levels, depending upon the process used to make it. It may be desirable to remove impurities from layer 214, and to oxidize it to generate a layer with a nearly idealized metal:oxygen stoichiometry, after layer 214 is deposited.

To remove impurities from that layer and to increase that layer's oxygen content, a wet chemical treatment may be applied to high-k gate dielectric layer 214. Such a wet chemical treatment may comprise exposing high-k gate dielectric layer 214 to a solution that comprises hydrogen peroxide at a sufficient temperature for a sufficient time to remove impurities from high-k gate dielectric layer 214 and to increase the oxygen content of high-k gate dielectric layer 214. The appropriate time and temperature at which high-k gate dielectric layer 214 is exposed may depend upon the desired thickness and other properties for high-k gate dielectric layer 214.

When high-k gate dielectric layer 214 is exposed to a hydrogen peroxide based solution, an aqueous solution that contains between about 2% and about 30% hydrogen peroxide by volume may be used. That exposure step should take place at between about 15° C. and about 40° C. for at least about one minute. In a particularly preferred embodiment, high-k gate dielectric layer 214 is exposed to an aqueous solution that contains about 6.7% H₂O₂ by volume for about 10 minutes at a temperature of about 25° C. During that exposure step, it may be desirable to apply sonic energy at a frequency of between about 10 KHz and about 2,000 KHz, while dissipating at between about 1 and about 10 watts/cm². In a preferred embodiment, sonic energy may be applied at a frequency of about 1,000 KHz, while dissipating at about 5 watts/cm².

Although not shown in FIG. 2e, it may be desirable to form a capping layer, which is no more than about five monolayers thick, on high-k gate dielectric layer 214., Such a capping layer may be formed by sputtering one to five monolayers of silicon, or another material, onto the surface of high-k gate dielectric layer 214. The capping layer may then be oxidized, e.g., by using a plasma enhanced chemical vapor deposition process or a solution that contains an oxidizing agent, to form a capping dielectric oxide.

Although in some embodiments it may be desirable to form a capping layer on gate dielectric layer 214, in the illustrated embodiment, n-type metal layer 215 is formed directly on layer 214 to fill trench 213 and to generate the FIG. 2f structure. N-type metal layer 215 may comprise any n-type conductive material from which a metal NMOS gate electrode may be derived. Materials that may be used to form n-type metal layer 215 include: hafnium, zirconium, titanium, tantalum, aluminum, and their alloys, e.g., metal carbides that include these elements, i.e., hafnium carbide, zirconium carbide, titanium carbide, tantalum carbide, and aluminum carbide. N-type metal layer 215 may be formed on high-k gate dielectric layer 214 using well known PVD or CVD processes, e.g., conventional sputter or atomic layer CVD processes. As shown in FIG. 2g, n-type metal layer 215 is removed except where it fills trench 213. Layer 215 may be removed from other portions of the device via a wet or dry etch process, or an appropriate CMP operation. Dielectric 212 may serve as an etch or polish stop, when layer 215 is removed from its surface.

N-type metal layer 215 preferably serves as a metal NMOS gate electrode that has a workfunction that is between about 3.9 eV and about 4.2 eV, and that is between about 100 angstroms and about 2,000 angstroms thick, and more preferably is between about 500 angstroms and about 1,600 angstroms thick. Although FIGS. 2f and 2g represent structures in which n-type metal layer 215 fills all of trench 213, in alternative embodiments, n-type metal layer 215 may fill only part of trench 213, with the remainder of the trench being filled with a material that may be easily polished, e.g., tungsten, aluminum, titanium, or titanium nitride. In such an alternative embodiment, n-type metal layer 215, which serves as the workfunction metal, may be between about 50 and about 1,000 angstroms thick—and more preferably at least about 100 angstroms thick.

In embodiments in which trench 213 includes both a workfunction metal and a trench fill metal, the resulting metal NMOS gate electrode may be considered to comprise the combination of both the workfunction metal and the trench fill metal. If a trench fill metal is deposited on a workfunction metal, the trench fill metal may cover the entire device when deposited, forming a structure like the FIG. 2f structure. That trench fill metal must then be polished back so that it fills only the trench, generating a structure like the FIG. 2g structure.

In the illustrated embodiment, after forming n-type metal layer 215 within trench 213, polysilicon layer 206 is removed to generate trench 250 that is positioned between sidewall spacers 210 and 211—producing the structure shown in FIG. 2h. In a preferred embodiment, layer 206 is exposed to a solution that comprises between about 20 and about 30 percent TMAH by volume in deionized water for a sufficient time at a sufficient temperature (e.g., between about 60° C. and about 90° C.), while applying sonic energy, to remove all of layer 206 without removing significant portions of n-type metal layer 215.

Second dummy dielectric layer 207 may be removed and replaced with gate dielectric layer 260, using process steps like those identified above. Gate dielectric layer 260 preferably comprises a high-k gate dielectric layer. Optionally, as mentioned above, a capping layer (which may be oxidized after it is deposited) may be formed on gate dielectric layer 260 prior to filling trench 250 with a p-type metal. In this embodiment, however, after replacing layer 207 with layer 260, p-type metal layer 216 is formed directly on layer 260 to fill trench 250 and to generate the FIG. 2i structure. P-type metal layer 216 may comprise any p-type conductive material from which a metal PMOS gate electrode may be derived.

Materials that may be used to form p-type metal layer 216 include: ruthenium, palladium, platinum, cobalt, nickel, and conductive metal oxides, e.g., ruthenium oxide. P-type metal layer 216 may be formed on gate dielectric layer 260 using well known PVD or CVD processes, e.g., conventional sputter or atomic layer CVD processes. As shown in FIG. 2j, p-type metal layer 216 is removed except where it fills trench 250. Layer 216 may be removed from other portions of the device via a wet or dry etch process, or an appropriate CMP operation, with dielectric 212 serving as an etch or polish stop. P-type metal layer 216 may serve as a metal PMOS gate electrode with a workfunction that is between about 4.9 eV and about 5.2 eV, and that is between about 100 angstroms and about 2,000 angstroms thick, and more preferably is between about 500 angstroms and about 1,600 angstroms thick.

Although FIGS. 2i and 2j represent structures in which p-type metal layer 216 fills all of trench 250, in alternative embodiments, p-type metal layer 216 may fill only part of trench 250. As with the metal NMOS gate electrode, the remainder of the trench may be filled with a material that may be easily polished, e.g., tungsten, aluminum, titanium, or titanium nitride. In such an alternative embodiment, p-type metal layer 216, which serves as the workfunction metal, may be between about 50 and about 1,000 angstroms thick. Like the metal NMOS gate electrode, in embodiments in which trench 250 includes a workfunction metal and a trench fill metal, the resulting metal PMOS gate electrode may be considered to comprise the combination of both the workfunction metal and the trench fill metal.

Although a few examples of materials that may be used to form dummy dielectric layers 205 and 207 and metal layers 215 and 216 are described here, those dummy dielectric layers and those metal layers may be made from many other materials, as will be apparent to those skilled in the art. Although this embodiment illustrates forming a metal NMOS gate electrode prior to forming a metal PMOS gate electrode, alternative embodiments may form a metal PMOS gate electrode prior to forming a metal NMOS gate electrode.

After removing metal layer 216, except where it fills trench 250, a capping dielectric layer (not shown) may be deposited onto dielectric layer 212, metal NMOS gate electrode 215, and metal PMOS gate electrode 216, using any conventional deposition process. Process steps for completing the device that follow the deposition of such a capping dielectric layer, e.g., forming the device's contacts, metal interconnect, and passivation layer, are well known to those skilled in the art and will not be described here.

Because the method described above facilitates formation of a relatively thick hard mask on a dummy gate electrode, it may enable a replacement gate process that replaces polysilicon layers with metal layers, which is not adversely affected by silicide formation on the polysilicon layers. Although the foregoing description has specified certain steps and materials that may be used in the present invention, those skilled in the art will appreciate that many modifications and substitutions may be made. Accordingly, it is intended that all such modifications, alterations, substitutions and additions be considered to fall within the spirit and scope of the invention as defined by the appended claims.

1. A method for making a semiconductor device comprising:
forming a sacrificial layer on a substrate;
forming a trench within the sacrificial layer;
forming a dummy gate electrode within the trench; and
forming a hard mask on the dummy gate electrode and within the trench.

2. The method of claim 1 wherein the sacrificial layer is a dielectric layer, the dummy gate electrode comprises polysilicon, and the hard mask comprises silicon nitride.

3. The method of claim 2 wherein the sacrificial layer comprises silicon dioxide and further comprising removing substantially all of the sacrificial layer after forming the hard mask to expose first and second sides of the dummy gate electrode.

4. The method of claim 3 wherein the sacrificial layer is formed on an etch stop layer, the etch stop layer is formed on a dummy gate dielectric layer, and the dummy gate dielectric layer is formed on the substrate.

5. The method of claim 4 wherein the etch stop layer comprises a first silicon nitride layer, and wherein the trench is formed by removing part of the sacrificial layer, then removing the underlying part of the first silicon nitride layer.

6. The method of claim 5 further comprising:
forming a second silicon nitride layer on the first silicon nitride layer, on the first and second sides of the dummy gate electrode and on the hard mask after removing substantially all of the sacrificial layer, then
removing the second silicon nitride layer and the first silicon nitride layer from the dummy gate dielectric layer, and
removing the second silicon nitride layer from the hard mask to generate first and second spacers that comprise silicon nitride on the first and second sides of the dummy gate electrode.

7. The method of claim 6 wherein the second silicon nitride layer is removed from the hard mask at the same time that the second silicon nitride layer and the first silicon nitride layer are removed from the dummy gate dielectric layer.

8. A method for making a semiconductor device comprising:
forming a first dielectric layer on a substrate;
forming an etch stop layer on the first dielectric layer;
forming a sacrificial layer on the etch stop layer;
forming a trench within the sacrificial layer by removing part of the sacrificial layer and the underlying part of the etch stop layer;
forming a polysilicon containing layer within the trench;
forming a hard mask on the polysilicon containing layer and within the trench;
removing substantially all of the sacrificial layer to expose first and second sides of the polysilicon containing layer;
forming a silicon nitride layer on the etch stop layer, on the first and second sides of the polysilicon containing layer and on the hard mask;
removing the silicon nitride layer and the etch stop layer from the first dielectric layer; and
removing the silicon nitride layer from the hard mask to generate first and second spacers that comprise silicon nitride on the first and second sides of the polysilicon containing layer.

9. The method of claim 8 wherein the sacrificial layer is a second dielectric layer, the etch stop layer comprises silicon nitride, and the hard mask comprises silicon nitride.

10. The method of claim 9 wherein the first dielectric layer comprises silicon dioxide, the second dielectric layer comprises silicon dioxide, and wherein the silicon nitride layer is removed from the hard mask while the silicon nitride layer and the etch stop layer are removed from the first dielectric layer.

11. A method for making a semiconductor device comprising:
forming a first silicon dioxide layer on a substrate;
forming a first silicon nitride layer on the first silicon dioxide layer;
forming a second silicon dioxide layer on the first silicon nitride layer;
removing part of the second silicon dioxide layer to expose part of the first silicon nitride layer;
removing the exposed part of the first silicon nitride layer to create a first trench within the second silicon dioxide layer;
forming a polysilicon containing layer within the first trench;
forming a hard mask on the polysilicon containing layer and within the first trench;
removing substantially all of the second dielectric layer to expose first and second sides of the polysilicon containing layer;
forming a second silicon nitride layer on the first silicon nitride layer, on the first and second sides of the polysilicon containing layer and on the hard mask;
removing the second silicon nitride layer and the first silicon nitride layer from the first silicon dioxide layer;
removing the second silicon nitride layer from the hard mask to generate first and second spacers that comprise silicon nitride on the first and second sides of the polysilicon containing layer;
removing the hard mask, the polysilicon containing layer, and the underlying part of the first silicon dioxide layer to generate a second trench that is positioned between the first and second spacers;
forming a high-k gate dielectric layer on the substrate at the bottom of the second trench; and
filling at least part of the second trench with a metal layer that is formed on the high-k gate dielectric layer.

12. The method of claim 11 wherein:
the high-k gate dielectric layer comprises a material that is selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate; and
the metal layer fills the entire second trench and comprises a material that is selected from the group consisting of hafnium, zirconium, titanium, tantalum, aluminum, a metal carbide, ruthenium, palladium, platinum, cobalt, nickel, and a conductive metal oxide.

13. The method of claim 11 wherein the metal layer comprises a material that is selected from the group consisting of hafnium, zirconium, titanium, tantalum, aluminum, and a metal carbide, and has a workfunction that is between about 3.9 eV and about 4.2 eV.

14. The method of claim 11 wherein the metal layer comprises a material that is selected from the group consisting of ruthenium, palladium, platinum, cobalt, nickel, and a conductive metal oxide, and has a workfunction that is between about 4.9 eV and about 5.2 eV.

15. The method of claim 11 further comprising:
forming within the second trench a workfunction metal that is between about 50 and about 1,000 angstroms thick; and
forming on the workfunction metal a trench fill metal that is selected from the group consisting of tungsten, aluminum, titanium, and titanium nitride.
